(19) United States
(12) Patent Application Publication
(10) Pub. No.: US 2025/0241190 A1
(43) Pub. Date: Jul. 24, 2025

(54) DISPLAY DEVICE AND ELECTRONIC DEVICE INCLUDING THE SAME

(71) Applicant: Samsung Display Co., LTD., Yongin-si (KR)

(72) Inventors: HIDEKAZU HAYASHI, Yongin-si (KR); JAHUN KOO, Yongin-si (KR); BYUNG-GON KUM, Yongin-si (KR); DA WN KIM, Yongin-si (KR); JI SANG SEO, Yongin-si (KR); TAEK-SUN SHIN, Yongin-si (KR)

(73) Assignee: Samsung Display Co., LTD., Yongin-si (KR)

(21) Appl. No.: 19/001,981

(22) Filed: Dec. 26, 2024

(30) Foreign Application Priority Data
Jan. 22, 2024 (KR) 10-2024-0009293

(51) Int. Cl. H10K 59/80

(52) U.S. Cl. CPC H10K 59/8794

(57) ABSTRACT

A display device includes a display panel including a light emitting element and a heat dissipation sheet disposed under the display panel and including a heat dissipation layer, a first protective layer disposed under the heat dissipation layer and defining a plurality of first through holes, and a water-repellent member disposed under the first protective layer, having a water-repellent surface, and defining a plurality of second through holes corresponding to the plurality of first through holes.

### CROSS-REFERENCE TO RELATED APPLICATION

This application claims priority to and benefits of Korean Patent Application No. 10-2024-0009293 under 35 U.S.C. § 119, filed on Jan. 22, 2024 in the Korean Intellectual Property Office (KIPO), the entire contents of which are incorporated herein by reference.

### BACKGROUND

### 1. Technical Field

The disclosure relates to a display device. More specifically, the disclosure relates to a display device including a heat dissipation sheet.

### 2. Description of the Related Art

As information technology develops, the importance of a display device as a connection medium between a user and information is being highlighted. The display device may include a heat dissipation sheet to dissipate heat generated from a display panel to the outside.

### SUMMARY

Embodiments provide a display device with improved durability.

A display device according to an embodiment may include a display panel including a light emitting element and a heat dissipation sheet disposed under the display panel and including a heat dissipation layer, a first protective layer disposed under the heat dissipation layer and defining first through holes, and a water-repellent member disposed under the first protective layer, having a water-repellent surface, and defining second through holes corresponding to the first through holes.

In an embodiment, a contact angle of a surface of the water-repellent member with respect to water may be greater than a contact angle of a surface of the first protective layer with respect to water.

In an embodiment, the contact angle of the surface of the water-repellent member with respect to water may be about 90 degrees or more.

In an embodiment, the water-repellent member may cover a surface of the first protective layer around each of the first through holes.

In an embodiment, the water-repellent member may include at least one of a fluorine-based compound and a silicon-based compound.

In an embodiment, one of the plurality of first through holes and a corresponding one of the plurality of second through holes may be spatially connected to each other.

In an embodiment, the first protective layer may include a first resin film disposed between the heat dissipation layer and the water-repellent member and a first adhesive layer disposed between the first resin film and the heat dissipation layer, and each of the first through holes may include a first sub-hole penetrating the first adhesive layer and a second sub-hole penetrating the first resin film.

In an embodiment, the heat dissipation sheet may further include a second protective layer disposed above the heat dissipation layer, and the second protective layer may include a second resin film disposed between the heat dissipation layer and the display panel and a second adhesive layer disposed between the second resin film and the heat dissipation layer.

In an embodiment, the heat dissipation sheet may include a first area and a second area positioned outside the first area, the first protective layer and the second protective layer may be non-contact in the first area and contact each other in the second area, and the water-repellent member may overlap the first area in a plan view.

In an embodiment, the first through holes and the second through holes may be defined in the first area.

In an embodiment, the water-repellent member may be a water-repellent film disposed in an integrated shape under the first protective layer and in which the second through holes are defined.

In an embodiment, the water-repellent member may include water-repellent patterns disposed under the first protective layer.

In an embodiment, the water-repellent patterns may be arranged to correspond to positions where the first through holes are defined.

In an embodiment, a planar shape of each of the water-repellent patterns may be a ring-shape, and each of the water-repellent patterns may define one of the second through holes.

In an embodiment, a surface of the water-repellent member may have a concave-convex structure around the second through holes.

In an embodiment, a width of each of the second through holes may decrease as a distance from the heat dissipation layer increases.

In an embodiment, the heat dissipation layer may include graphite.

A display device according to an embodiment may include a display panel and a heat dissipation sheet disposed under the display panel, and the display panel may include a base substrate, a transistor disposed on the base substrate, and a light emitting element electrically connected to the transistor, and the heat dissipation sheet may include a heat dissipation layer disposed under the display panel, including graphite, and having a porous structure, a first protective layer disposed under the heat dissipation layer and defining first through holes, a water-repellent member disposed under the first protective layer, having a water-repellent surface, and defining second through holes corresponding to the first through holes, and a second protective layer disposed above the heat dissipation layer.

In an embodiment, a contact angle of a surface of the water-repellent member with respect to water may be greater than a contact angle of a surface of the first protective layer with respect to water, and the contact angle of the surface of the water-repellent member with respect to water may be about 90 degrees or more.

In an embodiment, the heat dissipation sheet may include a first area and a second area positioned outside the first area, the first protective layer and the second protective layer may be non-contact in the first area and contact each other in the second area, the water-repellent member may overlap the first area in a plan view, and the first through holes and the second through holes may be defined in the first area.

An electronic device according to an embodiment may include a display device and a processor which controls the display device, the display device includes: a display panel including a light emitting element and a heat dissipation sheet disposed under the display panel and including: a heat dissipation layer, a first protective layer disposed under the heat dissipation layer and defining a plurality of first through holes, and a water-repellent member disposed under the first protective layer, having a water-repellent surface, and defining a plurality of second through holes corresponding to the plurality of first through holes.

In the display device according to embodiments, a heat dissipation sheet may be disposed under a display panel. The heat dissipation sheet may include a heat dissipation layer disposed under the display panel and a first protective layer disposed under the heat dissipation layer, and the first protective layer may define first through holes exposing a portion of the heat dissipation layer. Movement of air may occur through the first through holes, thereby a pressure difference between the outside and inside of the heat dissipation sheet may be reduced. Accordingly, a phenomenon of the protective layer being detached from the heat dissipation layer due to the pressure difference may be prevented. Accordingly, durability of the display device may be improved.

The heat dissipation sheet may further include a water-repellent member. The water-repellent member may be disposed under the first protective layer, have a water-repellent surface, and define second through holes corresponding to the first through holes. The water-repellent member may prevent moisture from infiltrating through the first through holes of the protective layer. Accordingly, the phenomenon of the protective layer being detached from the heat dissipation layer due to infiltrated moisture may be prevented. Accordingly, the durability of the display device may be improved.

As the water-repellent member defines the second through holes, movement of air through the first through holes may not be blocked even in case that the water-repellent member is disposed below the first protective layer. Accordingly, a function of the first through holes to adjust the pressure difference between the outside and inside of the heat dissipation sheet may be maintained.

It is to be understood that both the foregoing general description and the following detailed description are explanatory and are intended to provide further explanation of the invention as claimed.

### BRIEF DESCRIPTION OF THE DRAWINGS

Illustrative, non-limiting embodiments will be more clearly understood from the following detailed description taken in conjunction with the accompanying drawings.

FIG. 1 is a schematic perspective view illustrating a display device according to an embodiment.

FIG. 2 is a schematic cross-sectional view illustrating the display panel included in the display device of FIG. 1.

FIG. 3 is a schematic perspective view illustrating an example of a heat dissipation sheet included in the display device of FIG. 1.

FIG. 4 is a schematic cross-sectional view illustrating an example taken along line I-I′ of FIG. 3.

FIG. 5 is a schematic enlarged view of area XX in FIG. 3.

FIG. 6 is a schematic cross-sectional view illustrating another example taken along line I-I′ of FIG. 3.

FIG. 7 is a schematic cross-sectional view illustrating still another example taken along line I-I′ of FIG. 3.

FIG. 8 is a schematic perspective view illustrating another example of a heat dissipation sheet included in the display device of FIG. 1.

FIG. 9 is a schematic cross-sectional view illustrating an example taken along line II-II′ of FIG. 8.

FIG. 10 is a schematic enlarged view of area YY of FIG. 8.

FIG. 11 is a schematic cross-sectional view illustrating another example taken along line II-II′ of FIG. 8.

FIG. 12 is a schematic cross-sectional view illustrating still another example taken along line II-II′ of FIG. 8.

FIG. 13 is a schematic block diagram illustrating an electronic device according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

It will be understood that when an element such as a layer, film, region, or substrate is referred to as being “on” or “over” another element, it can be directly on the other element or intervening element(s) may also be present. In contrast, when an element is referred to as being “directly on” another element, no intervening elements are present.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, display devices in accordance with embodiments will be described in more detail with reference to the accompanying drawings. The same reference numerals are used for the same components in the drawings, and redundant descriptions of the same components will be omitted.

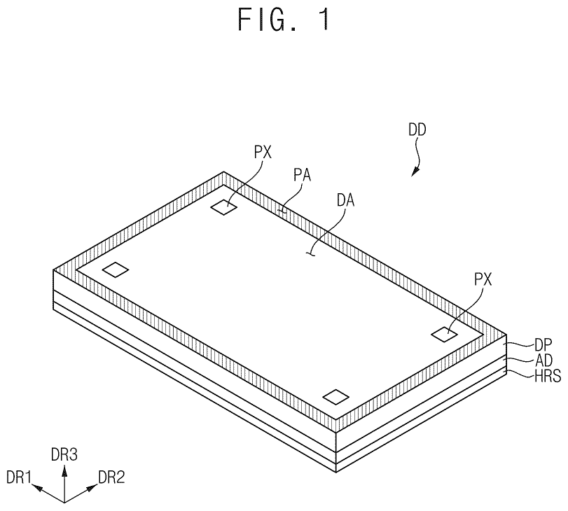

FIG. 1 is a schematic perspective view illustrating a display device according to an embodiment.

Referring to FIG. 1, a display device DD may include a display panel DP, an adhesive member AD, and a heat dissipation sheet HRS.

The display panel DP may be a light-emitting display panel. For example, the display panel DP may be an organic light-emitting display panel including an organic light-emitting element or an inorganic light-emitting display panel including an inorganic light-emitting element. However, the disclosure is not necessarily limited thereto.

The display panel DP may include a display area DA and a peripheral area PA. The display area DA may be an area that displays an image. A planar shape of the display area DA may be rectangular. However, the planar shape of the display area DA is not limited thereto, and the display area DA may have various planar shapes other than a rectangle.

The peripheral area PA may be an area that does not display images. The peripheral area PA may be arranged around the display area DA. For example, the peripheral area PA may entirely surround the display area DA. In an embodiment, drivers for displaying images in the display area DA may be disposed in the peripheral area PA.

The display panel DP may include pixels PX. Pixels PX may be arranged in the display area DA. The pixels PX may be arranged in a matrix form along a first direction DR1 and a second direction DR2 that intersects the first direction DR1.

The display panel DP may have a rectangular planar shape. However, the present invention is not limited thereto, and the display panel DP may have various planar shapes other than a rectangular planar shape.

In this specification, a plane may be defined by the first direction DR1 and the second direction DR2. For example, the first direction DR1 may be perpendicular to the second direction DR2. A third direction DR3 may be a normal direction to the plane. For example, the third direction DR3 may be perpendicular to both the first direction DR1 and the second direction DR2.

The heat dissipation sheet HRS may be disposed under the display panel DP. The heat dissipation sheet HRS may be bonded to a lower surface of the display panel DP through the adhesive member AD. For example, the adhesive member AD may be a pressure-sensitive adhesive layer, but the disclosure is not necessarily limited thereto.

The heat dissipation sheet HRS may dissipate heat generated in the display panel DP to the outside. For example, the heat dissipation sheet HRS may have substantially the same planar shape as the display panel DP, and the heat dissipation sheet HRS may have an area (or planar size) substantially the same as the display panel DP. However, the disclosure is not necessarily limited thereto.

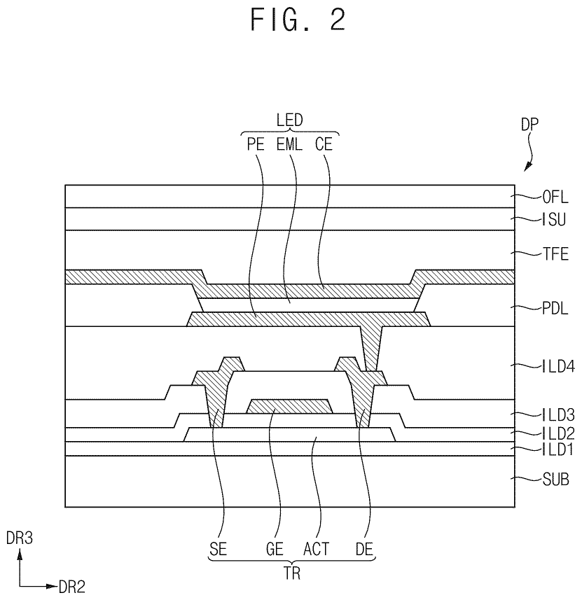

FIG. 2 is a schematic cross-sectional view illustrating the display panel included in the display device of FIG. 1.

Referring to FIGS. 1 and 2, the display panel DP may include a base substrate SUB, a transistor TR, first to fourth insulating layers ILD1, ILD2, ILD3, and ILD4, a pixel defining layer PDL, a light emitting element LED, an encapsulation layer TFE, an input sensing layer ISU, and an optical functional layer OFL. For example, the transistor TR may include an active pattern ACT, a gate electrode GE, a first connection electrode SE, and a second connection electrode DE. The light emitting element LED may include a pixel electrode PE, an emission layer EML, and a common electrode CE.

The base substrate SUB may include a transparent or opaque material. In an embodiment, examples of materials that may be used as the base substrate SUB may include glass, quartz, plastic, or the like. These may be used alone or in combination with each other.

The first insulating layer ILD1 may be disposed on the base substrate SUB. The first insulating layer ILD1 may prevent metal atoms or impurities from diffusing from the base substrate SUB to the active pattern ACT. In an embodiment, the first insulating layer ILD1 may be formed of an insulating material. Examples of insulating materials that may be used as the first insulating layer ILD1 may include silicon oxide, silicon nitride, silicon oxynitride, or the like. These may be used alone or in combination with each other.

The active pattern ACT may be disposed on the first insulating layer ILD1. In an embodiment, the active pattern ACT may be formed of a silicon semiconductor material, an oxide semiconductor material, an organic semiconductor material, or the like. The active pattern ACT may include a source area, a drain area, and a channel area located between the source area and the drain area.

The second insulating layer ILD2 may be disposed on the active pattern ACT. The second insulating layer ILD2 may cover the active pattern ACT. In an embodiment, the second insulating layer ILD2 may be formed of an insulating material. Examples of insulating materials that may be used as the second insulating layer ILD2 may include silicon oxide, silicon nitride, silicon oxynitride, or the like. These may be used alone or in combination with each other.

The gate electrode GE may be disposed on the second insulating layer ILD2. The gate electrode GE may overlap the channel area of the active pattern ACT in a plan view. In an embodiment, the gate electrode GE may be formed of metal, alloy, conductive metal oxide, transparent conductive material, or the like. The gate electrode GE may have a single-layer structure or a multi-layer structure including conductive layers.

The third insulating layer ILD3 may be disposed on the gate electrode GE. The third insulating layer ILD3 may cover the gate electrode GE. In an embodiment, the third insulating layer ILD3 may be formed of an insulating material. Examples of insulating materials that may be used as the third insulating layer ILD3 may include silicon oxide, silicon nitride, silicon oxynitride, or the like. These may be used alone or in combination with each other.

The first connection electrode SE and the second connection electrode DE may be disposed on the third insulating layer ILD3. The first connection electrode SE and the second connection electrode DE may contact the source area and the drain area of the active pattern ACT, respectively. In an embodiment, the first connection electrode SE and the second connection electrode DE may be formed of metal, alloy, conductive metal oxide, transparent conductive material, or the like.

The fourth insulating layer ILD4 may be disposed on the first connection electrode SE and the second connection electrode DE. The fourth insulating layer ILD4 may cover the first connection electrode SE and the second connection electrode DE. The fourth insulating layer ILD4 may be formed of an insulating material. Examples of insulating materials that may be used as the fourth insulating layer ILD4 may include photoresist, polyacrylic resin, polyimide-based resin, polyamide-based resin, siloxane-based resin, acrylic resin, epoxy-based resin, or the like. These may be used alone or in combination with each other. The fourth insulating layer ILD4 may have a single-layer structure or a multi-layer structure including insulating layers.

The pixel electrode PE may be disposed on the fourth insulating layer ILD4. The pixel electrode PE may include conductive material such as a metal, alloy, conductive metal nitride, conductive metal oxide, transparent conductive material, or the like. The pixel electrode PE may have a single-layer structure or a multi-layer structure including conductive layers.

The pixel electrode PE may be electrically connected to the transistor TR through a contact hole formed in the fourth insulating layer ILD4.

The pixel defining layer PDL may be disposed on the fourth insulating layer ILD4 and the pixel electrode PE. The pixel defining layer PDL may be formed of an insulating material. Examples of insulating materials that may be used as the pixel defining layer PDL may include photoresist, polyacrylic resin, polyimide resin, polyamide resin, siloxane resin, acrylic resin, epoxy resin, or the like. These may be used alone or in combination with each other. The pixel defining layer PDL may define an opening which exposes at least a portion of the pixel electrode PE.

The emission layer EML may be disposed on the pixel electrode PE exposed by the opening of the pixel defining layer PDL. In an embodiment, the emission layer EML may have a multilayer structure including a hole injection layer, a hole transport layer, an electron transport layer, a light emitting material layer, and an electron injection layer.

The common electrode CE may be disposed on the emission layer EML. The common electrode CE may include a conductive material such as a metal, alloy, conductive metal nitride, conductive metal oxide, or transparent conductive material. The common electrode CE may have a single-layer structure or a multi-layer structure including conductive layers. In an embodiment, the common electrode CE may extend continuously on the display area DA across pixels.

The encapsulation layer TFE may be disposed on the common electrode CE. The encapsulation layer TFE may cover the light emitting element LED. The encapsulation layer TFE may prevent impurities from penetrating into the light emitting element LED. The encapsulation layer TFE may include at least one organic layer and at least one inorganic layer.

The input sensing layer ISU may be disposed on the encapsulation layer TFE. The input sensing layer ISU may detect external input. External input may be provided in various forms. For example, external input may be in a form of a user's touch, pen touch, light, heat, or pressure. External input may be in a form of a touch in an adjacent space (for example, hovering) as well as a direct contact. The input sensing layer ISU may include at least one touch electrode and at least one insulating layer. In an embodiment, the input sensing layer ISU may be omitted.

The optical functional layer OFL may be disposed on the encapsulation layer TFE. For example, the optical functional layer OFL may reduce a reflectance of incident light onto the display panel DP (e.g., external light). In an embodiment, the optical functional layer OFL may include a phase retarder and a polarizer. However, the disclosure is not necessarily limited thereto. For another example, the optical functional layer OFL may include a black matrix including a light blocking material and a color filter. The color filter may be set considering a color of light emitted from the light emitting element LED. In an embodiment, the optical functional layer OFL may be omitted.

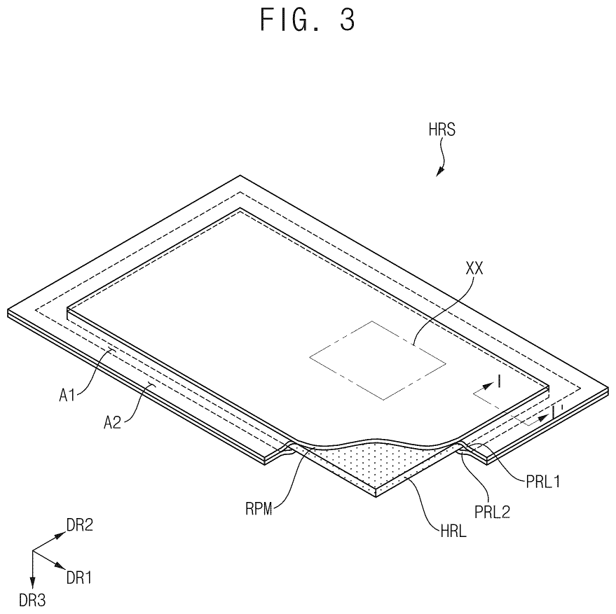

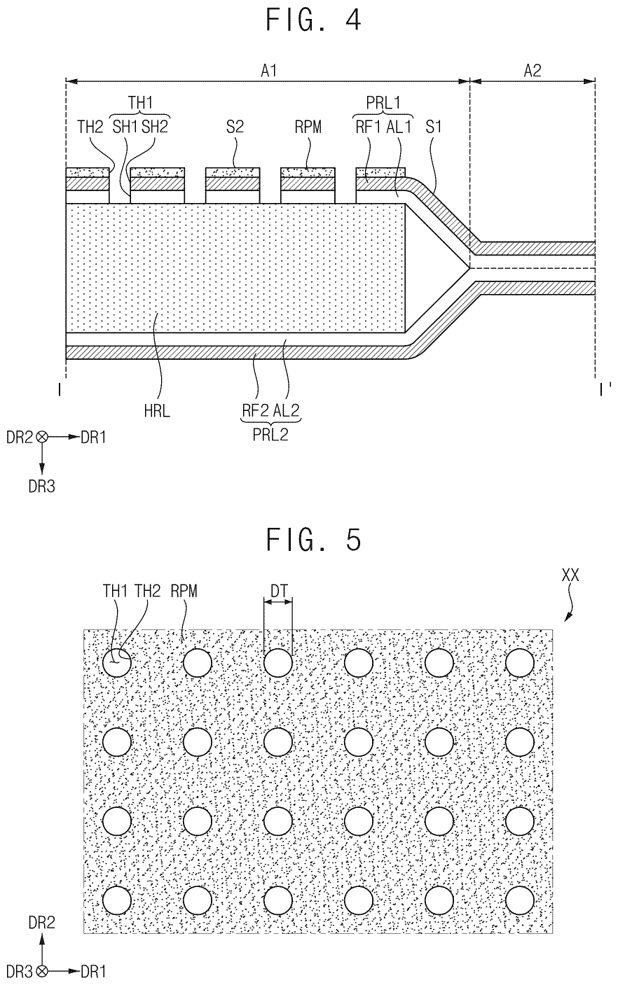

FIG. 3 is a schematic perspective view illustrating an example of a heat dissipation sheet included in the display device of FIG. 1. FIG. 4 is a schematic cross-sectional view illustrating an example taken along line I-I′ of FIG. 3. FIG. 5 is a schematic enlarged view enlarged view of area XX in FIG. 3.

An upper surface of the heat dissipation sheet HRS illustrated in FIGS. 3 to 5 may correspond to a lower surface of the heat dissipation sheet HRS with respect to FIG. 1. Accordingly, although it may be illustrated as an upper or an uppers surface in FIGS. 3 to 5, it may be described as a lower or lower surface for consistency with FIG. 1. Although it may be illustrated as a lower or lower surface in FIGS. 3 to 5, it may be described as an upper or upper surface for consistency with FIG. 1.

Referring to FIGS. 3 to 5, the heat dissipation sheet HRS may include a first area A1 and a second area A2. The second area A2 may be disposed outside the first area A1. The second area A2 may be an area where a seal is formed, and the first area A1 may be an area other than the second area A2.

The heat dissipation sheet HRS may include a heat dissipation layer HRL, a first protective layer PRL1, and a second protective layer PRL2.

The heat dissipation layer HRL may be disposed in the first area A1. The heat dissipation layer HRL may include a material with relatively high thermal conductivity. The heat dissipation layer HRL may have a porous structure. Examples of materials that may be used as the heat dissipation layer HRL may include tungsten-copper composite materials, molybdenum-copper composite materials, graphite, or the like. These may be used alone or in combination with each other. For example, the heat dissipation layer HRL may include graphite.

The first protective layer PRL1 and the second protective layer PRL2 may seal the heat dissipation layer HRL. Accordingly, the first protective layer PRL1 and the second protective layer PRL2 may prevent particles of the heat dissipation layer HRL from contaminating the outside of the heat dissipation sheet HRS. The first protective layer PRL1 and the second protective layer PRL2 may protect the heat dissipation layer HRL from external shock.

For example, the first protective layer PRL1 and the second protective layer PRL2 may contact each other in the second area A2. Accordingly, a seal may be formed in the second area A2. On the other hand, the first protective layer PRL1 and the second protective layer PRL2 may not contact each other in the first area A1.

The first protective layer PRL1 may be disposed under the heat dissipation layer HRL. The first protective layer PRL1 may define first through holes TH1. For example, the first through holes TH1 may penetrate the first protective layer PRL1. A portion of the heat dissipation layer HRL may be exposed through the first through holes TH1. The first through holes TH1 may be defined in the first area A1.

For example, as illustrated in FIG. 5, the first through holes TH1 may be arranged in a matrix form along the first direction DR1 and the second direction DR2. However, the disclosure is not necessarily limited thereto, and an arrangement of the first through holes TH1 may vary depending on embodiments.

In a manufacturing process of the display device DD, there may be a section in which pressure changes among process conditions. In the section, a phenomenon in which air is concentrated in an area where an adhesive force is relatively weak between the first protective layer PRL1 and the heat dissipation layer HRL may occur. Accordingly, a large pressure change may occur between the first protective layer PRL1 and the heat dissipation layer HRL. The pressure change may cause the first protective layer PRL1 to be detached from the heat dissipation layer HRL.

According to embodiments, movement of air may occur through the first through holes TH1 defined in the first protective layer PRL1, thereby a pressure difference between the outside and inside of the heat dissipation sheet HRS may be reduced. Accordingly, a phenomenon of the first protective layer PRL1 being detached from the heat dissipation layer HRL may be prevented. In particular, if the heat dissipation layer HRL has a porous structure including graphite, movement of air into the inside of the heat dissipation layer HRL may occur, the pressure difference between the outside and inside of the heat dissipation sheet HRS may be further reduced. Accordingly, the phenomenon of the first protective layer PRL1 being detached from the heat dissipation layer HRL may be further prevented.

The first protective layer PRL1 may include a first resin film RF1 and a first adhesive layer AL1. The first resin film RF1 may be bonded to the heat dissipation layer HRL through the first adhesive layer AL1.

The first resin film RF1 may include a polymer resin. Examples of materials that may be used as the first resin film RF1 may include acetal-based resin, acrylic-based resin, carbonate-based resin, ethylene-based resin, imide-based resin, or the like. These may be used alone or in combination with each other. For example, the first resin film RF1 may include polyethylene terephthalate.

In an embodiment, a surface of the first resin film RF1 may be electrically charged. For example, an antistatic layer may be formed on the surface of the first resin film RF1. Accordingly, a phenomenon of foreign substances adhering to the surface of the first resin film RF1 may be prevented. However, the disclosure is not necessarily limited thereto, and a charging treatment for the first resin film RF1 may be omitted.

The first adhesive layer AL1 may be disposed between the heat dissipation layer HRL and the first resin film RF1. In an embodiment, the first adhesive layer AL1 may include a heat-melted resin. As the first adhesive layer AL1 includes a heat-melted resin, the first adhesive layer AL1 may increase a strength of the first resin film RF1. For example, the first adhesive layer AL1 may include a urethane-based heat-melted resin.

The first adhesive layer AL1 may define first sub-holes SH1. For example, the first sub-holes SH1 may penetrate the first adhesive layer AL1. The first sub-holes SH1 may be defined in the first area A1.

The first resin film RF1 may define second sub-holes SH2. For example, the second sub-holes SH2 may penetrate the first resin film RF1. The second sub-holes SH2 may be defined in the second area A2.

The first through holes TH1 may be defined by the first sub-holes SH1 and second sub-holes SH2. For example, one of the first sub-holes SH1 and a corresponding one of the second sub-holes SH2 may be spatially connected to each other, accordingly, one of the first through holes TH1 may be defined. In other words, each of the first through holes TH1 may include a first sub-hole and a second sub-hole which are spatially connected to each other.

The second protective layer PRL2 may be disposed above the heat dissipation layer HRL. The second protective layer PRL2 may include a second resin film RF2 and a second adhesive layer AL2. The second resin film RF2 may be bonded to the heat dissipation layer HRL through the second adhesive layer AL2.

The second resin film RF2 may include polymer resin. Examples of materials that may be used as the second resin film RF2 may include acetal-based resin, acrylic-based resin, carbonate-based resin, ethylene-based resin, imide-based resin, or the like. These may be used alone or in combination with each other. For example, the second resin film RF2 may include polyethylene terephthalate.

In an embodiment, a surface of the second resin film RF2 may be electrically charged. For example, an antistatic layer may be formed on the surface of the second resin film RF2. Accordingly, a phenomenon of foreign substances adhering to the surface of the second resin film RF2 may be prevented. However, the disclosure is not necessarily limited thereto, and a charging treatment for the second resin film RF2 may be omitted.

The second adhesive layer AL2 may be disposed between the heat dissipation layer HRL and the second resin film RF2. In an embodiment, the second adhesive layer AL2 may include a heat-melted resin. As the second adhesive layer AL2 includes a heat-melted resin, the second adhesive layer AL2 may increase a strength of the second resin film RF2. For example, the second adhesive layer AL2 may include a urethane-based heat-melted resin.

In an embodiment, the first adhesive layer AL1 and the second adhesive layer AL2 may define one adhesive layer in the second area A2. For example, in case that forming a seal with the first protective layer PRL1 and the second protective layer PRL2, the first adhesive layer AL1 and the second adhesive layer AL2 may be compressed at a high temperature, cooled, and solidified to define one adhesive layer.

The heat dissipation sheet HRS may include a water-repellent member RPM. In this specification, water-repellent may mean preventing getting wet not only by water but also by all liquids, such as ink.

In an embodiment referring to FIGS. 3 to 5, the water-repellent member RPM may be a water-repellent film disposed in an integrated shape under the first protective layer PRL1 in which second through holes TH2 are defined. In other words, the water-repellent member RPM may be continuously extended without being disconnected. For example, the water-repellent member RPM may have a grid shape in which the second through holes TH2 are defined.

The water-repellent member RPM may be disposed under the first protective layer PRL1. The first protective layer PRL1 may be disposed between the heat dissipation layer HRL and the water-repellent member RPM. The water-repellent member RPM may be formed by spin coating, physical vapor deposition (PVD), chemical vapor deposition (CVD), or atomic layer deposition (ALD).

The water-repellent member RPM may include at least one of a fluorine-based compound and a silicon-based compound. For example, the water repellent member RPM may include polytetra teflon ethyleneglycol (PTFE) which is a teflon-based material.

The water-repellent member RPM may overlap the first area A1 in a plan view. For example, the water-repellent member RPM may be disposed in the first area A1 and not in the second area A2. However, the disclosure is not necessarily limited thereto, and the water-repellent member RPM may be disposed in the first area A1 and the second area A2.

In FIGS. 3 and 4, the water-repellent member RPM is illustrated to have the same area (or planar size) as the heat dissipation layer HRL and is disposed corresponding to an area where the heat dissipation layer HRL is disposed, but the disclosure is not necessarily limited thereto. For example, the water-repellent member RPM may be disposed beyond the heat dissipation layer HRL and up to a boundary between the first area A1 and the second area A2. The water-repellent member RPM may be disposed beyond the boundary between the first area A1 and the second area A2 and up to the second area A2. For example, the water-repellent member RPM may have a larger area (or planar size) than the heat dissipation layer HRL. The water-repellent member RPM may have a smaller area (or planar size) than the heat dissipation layer HRL.

As a result, in an area adjacent to the first through holes TH1 in the first area A1 (i.e., around each of the first through holes TH1), the water-repellent member RPM may be disposed under the first protective layer PRL1. Accordingly, the water-repellent member RPM may cover a first surface S1 of the first protective layer PRL1 around each of the first through holes TH1. On the other hand, a second surface S2 of the water-repellent member RPM may be exposed to the outside around each of the first through holes TH1.

A contact angle of the second surface S2 of the water repellent member RPM with respect to water may be greater than a contact angle of the first surface S1 of the first protective layer PRL1 with respect to water. For example, the second surface S2 of the water-repellent member RPM may be more hydrophobic than the first surface S1 of the first protective layer PRL1.

If a surface exposed to the outside around each of the first through holes TH1 has hydrophilicity, moisture may easily condense around each of the first through holes TH1, and moisture may infiltrate through the first through holes TH1. Moisture that has infiltrated may cause hydrolysis of the first adhesive layer AL1, causing detachment of the first adhesive layer AL1 from the heat dissipation layer HRL. Accordingly, the first protective layer PRL1 may be detached from the heat dissipation layer HRL.

According to embodiments, as the water-repellent member RPM is disposed under the first protective layer PRL1 around each of the first through holes TH1, infiltration of moisture through the first through holes TH1 may be prevented. Specifically, infiltration of moisture through the first through holes TH1 may be prevented compared to a case where the first surface S1 of the first protective layer PRL1 is exposed to the outside around each of the first through holes TH1. Accordingly, detachment of the first adhesive layer AL1 may be prevented, and detachment of the first protective layer PRL1 may be prevented. Accordingly, durability of the display device DD may be improved.

The contact angle of the second surface S2 of the water-repellent member RPM with respect to water may be about 90 degrees or more. Specifically, the contact angle of the second surface S2 of the water-repellent member RPM with respect to water may be more than about 90 degrees and less than about 180 degrees. In an embodiment, the contact angle of the second surface S2 of the water-repellent member RPM with respect to water may be more than about 120 degrees and less than about 180 degrees. In case that the contact angle of the second surface S2 of the water-repellent member RPM with respect to water is less than about 90 degrees, excessive moisture may infiltrate through the first through holes TH1. Therefore, it is desirable that the contact angle of the second surface S2 of the water repellent member RPM with respect to water is about 90 degrees or more.

In embodiments, the water-repellent member RPM may define the second through holes TH2. The second through holes TH2 may penetrate the water-repellent member RPM. For example, the water-repellent member RPM may be a grid-shaped water-repellent film in which the second through holes TH2 are defined. The second through holes TH2 may be defined in the first area A1.

As illustrated in FIGS. 4 and 5, the second through holes TH2 may be defined to correspond to positions where the first through holes TH1 are defined. In other words, the second through holes TH2 may have substantially the same arrangement as the first through holes TH1. For example, the second through holes TH2 may be arranged in a matrix form along the first direction DR1 and the second direction DR2. However, the disclosure is not necessarily limited thereto, and the arrangement of the second through holes TH2 may be changed in various ways to correspond to the arrangement of the first through holes TH1.

As a result, one of the first through holes TH1 and a corresponding one of the second through holes TH2 may be spatially connected to each other. Accordingly, a portion of the heat dissipation layer HRL may be exposed by the first through holes TH1 and the second through holes TH2.

As the water-repellent member RPM defines the second through-holes TH2, even in case that the water-repellent member RPM is disposed under the first protective layer PRL1, movement of air through the first through holes TH1 may not be blocked. Accordingly, a function of the first through holes TH1 to adjust the pressure difference between the outside and inside of the heat dissipation sheet HRS may be maintained.

As a result, movement of air may occur through the first through holes TH1 defined by the first protective layer PRL1 and the second through holes TH2 defined by the water-repellent member RPM, and thereby the pressure difference between the outside and inside of the heat dissipation sheet HRS may be reduced. Accordingly, the phenomenon of the first protective layer PRL1 being detached from the heat dissipation layer HRL may be prevented.

A maximum length of each of the second through holes TH2 in the first direction DR1 (or the second direction DR2) may be about 1 mm or less. If the maximum length exceeds about 1 mm, particles in the heat dissipation layer HRL may be released to the outside, causing damage to the display panel DP, and external foreign substances and moisture may infiltrate into the heat dissipation layer HRL. Specifically, the maximum length may be about 0.1 mm to about 1 mm. In an embodiment, the maximum length may be about 0.1 mm to about 0.4 mm.

For example, as illustrated in FIG. 5, each of the second through holes TH2 may have a circular planar shape. A diameter DT of each of the second through holes TH2 may be about 0.1 mm to about 1 mm. In an embodiment, the diameter DT may be about 0.1 mm to about 0.4 mm. However, the disclosure is not necessarily limited thereto, and a planar shape of the second through holes TH2 may vary depending on embodiments.

In an embodiment, a planar shape of each of the first through holes TH1 and a planar shape of each of the second through holes TH2 may be substantially the same. An area (or planar size) of each of the first through holes TH1 and an area (or planar size) of each of the second through holes TH2 may be substantially the same. A maximum length of each of the first through holes TH1 in the first direction DR1 (or the second direction DR2) and the maximum length of each of the second through holes TH2 in the first direction DR1 (or the second direction DR2) may be substantially the same. However, the disclosure is not necessarily limited thereto.

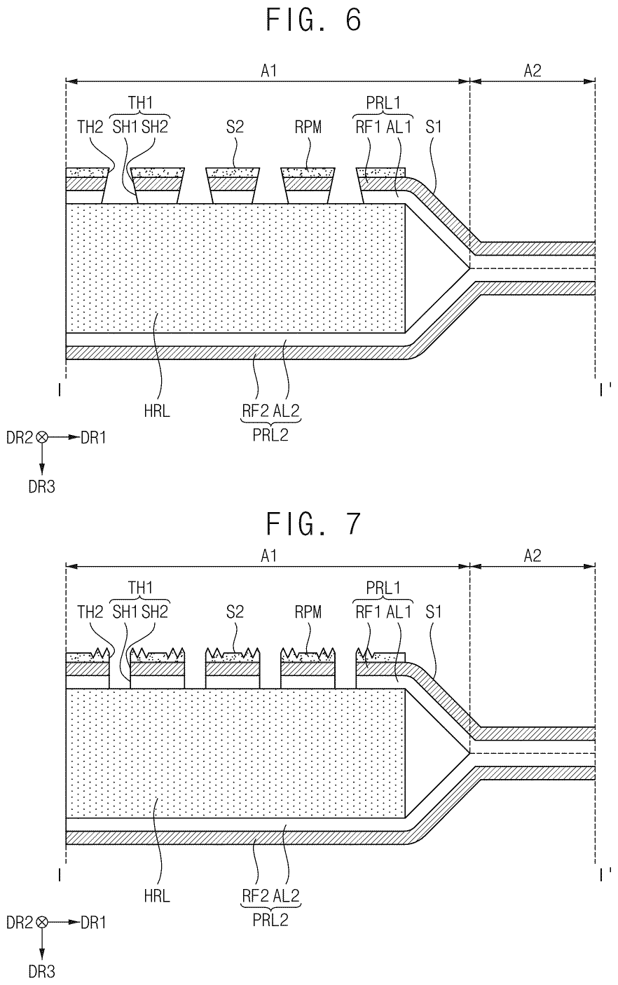

FIG. 6 is a schematic cross-sectional view illustrating another example taken along line I-I′ of FIG. 3.

An embodiment described with reference to FIG. 6 may be substantially the same as an embodiment described with reference to FIG. 4 except for a cross-sectional shape of each of the first through holes TH1 and the second through holes TH2. Therefore, overlapping descriptions are omitted.

In FIG. 4, each of the first through holes TH1 and the second through holes TH2 is illustrated to have a rectangular cross-sectional shape, but the disclosure is not necessarily limited thereto.

Referring to FIG. 6, a cross-sectional shape of each of the first through holes TH1 and the second through holes TH2 may be a taper shape. Specifically, a width of each of the first through holes TH1 and the second through holes TH2 may decrease as a distance from the heat dissipation layer HRL increases. In other words, each of the first through holes TH1 and the second through holes TH2 may be a taper shape whose width decreases toward an opposite direction of the third direction DR3 (i.e., toward lower surface of the heat dissipation sheet HRS). Accordingly, infiltration of moisture through the first through holes TH1 and/or the second through holes TH2 may be further prevented. Accordingly, detachment of the first protective layer PRL1 may be further prevented.

FIG. 7 is a schematic cross-sectional view illustrating still another example taken along line I-I′ of FIG. 3.

An embodiment described with reference to FIG. 7 may be substantially the same as an embodiment described with reference to FIG. 4 except for a concave-convex structure of the water-repellent member RPM. Therefore, overlapping descriptions are omitted.

In FIG. 4, the second surface S2 of the water-repellent member RPM is illustrated to have substantially no steps around the second through holes TH2, but the disclosure is not necessarily limited thereto.

Referring to FIG. 7, the second surface S2 of the water-repellent member RPM may have a concavo-convex structure around the second through holes TH2. The concavo-convex structure may be a structure in which at least one concave portion and at least one convex portion are repeated. Due to the concavo-convex structure, a roughness of the second surface S2 of the water-repellent member RPM around the second through holes TH2 may be improved. Accordingly, the contact angle of the second surface S2 of the water-repellent member RPM with respect to water around the second through holes TH2 may increase. Accordingly, infiltration of moisture through the first through holes TH1 and/or the second through holes TH2 may be further prevented. Accordingly, detachment of the first protective layer PRL1 may be further prevented.

In an embodiment, a length of each of the concave portion and the convex portion in the first direction DR1 may be about 1 micrometer or less. In case that the length of each of the concave portion and the convex portion in the first direction DR1 satisfies the above-mentioned range, the roughness of the second surface S2 of the water-repellent member RPM around the second through holes TH2 may be further improved. However, the length of each of the concave portion and the convex portion in the first direction DR1 is not necessarily limited thereto.

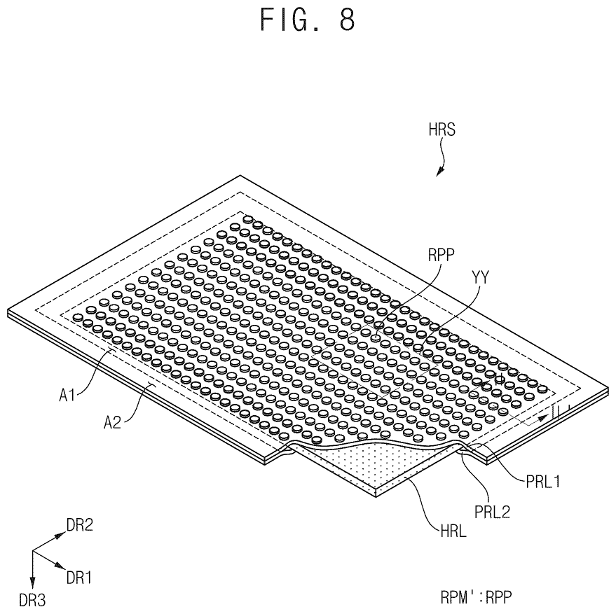

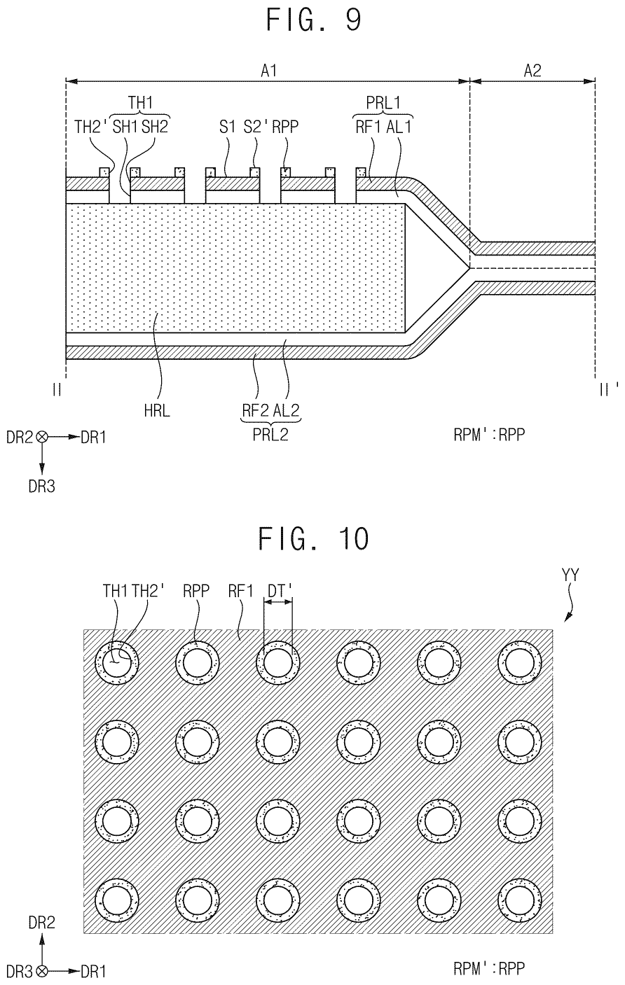

FIG. 8 is a schematic perspective view illustrating another example of a heat dissipation sheet included in the display device of FIG. 1. FIG. 9 is a schematic cross-sectional view illustrating an example taken along line II-II′ of FIG. 8. FIG. 10 is a schematic enlarged view of area YY of FIG. 8.

An upper surface of the heat dissipation sheet HRS illustrated in FIGS. 8 to 10 may correspond to a lower surface of the heat dissipation sheet HRS with respect to FIG. 1. Accordingly, although it may be illustrated as an upper or an uppers surface in FIGS. 8 to 10, it may be described as a lower or lower surface for consistency with FIG. 1. Although it may be illustrated as a lower or lower surface in FIGS. 8 to 10, it may be described as an upper or upper surface for consistency with FIG. 1.

The heat dissipation sheet HRS of FIGS. 8 to 10 may be substantially the same as the heat dissipation sheet HRS of FIGS. 3 to 5 except for the water-repellent member RPM'. Therefore, overlapping descriptions are omitted or simplified.

The water-repellent member RPM' of FIGS. 8 to 10 is different from the water-repellent member RPM of FIGS. 3 to 5 which has an integrated film structure, in that the water-repellent member RPM' has a structure including water-repellent patterns RPP. Except for this, the water-repellent member RPM' of FIGS. 8 to 10 may be substantially the same as the water-repellent member RPM of FIGS. 3 to 5. Therefore, overlapping descriptions are omitted or simplified.

Referring to FIGS. 8 to 10, in an embodiment, the water-repellent member RPM' may include the water-repellent patterns RPP. The water-repellent patterns RPP may be formed by inkjet printing, offset printing, or the like. The water-repellent member RPM' may be disposed under the first protective layer PRL1.

The water-repellent member RPM' may overlap the first area A1 in a plan view. Specifically, the water-repellent patterns RPP of the water repellent member RPM' may be arranged to correspond to positions where the first through holes TH1 are defined. As illustrated in FIGS. 8 and 10, the water-repellent patterns RPP may have substantially the same arrangement form as the first through holes TH1. For example, the water-repellent patterns RPP may be arranged in a matrix form along the first direction DR1 and the second direction DR2. However, the disclosure is not necessarily limited thereto, and the arrangement of the water-repellent patterns RPP may be changed in various ways according to the arrangement of the first through holes TH1.

In embodiments, the water-repellent member RPM' may define second through holes TH2′. Specifically, each of the water-repellent patterns RPP may define one second through hole among the second through holes TH2′. For example, a planar shape of each of the water-repellent patterns RPP may be a ring-shape. Each of the water-repellent patterns RPP may surround one first through hole of the first through holes TH1 in a plan view.

As the water-repellent member RPM' defines the second through-holes TH2′, even in case that the water-repellent member RPM' is disposed under the first protective layer PRL1, movement of air through the first through holes TH1 may not be blocked. Accordingly, the function of the first through holes TH1 to adjust the pressure difference between the outside and inside of the heat dissipation sheet HRS may be maintained.

Movement of air may occur through the first through holes TH1 defined by the first protective layer PRL1 and the second through holes TH2′ defined by the water-repellent member RPM', and thereby the pressure difference between the outside and inside of the heat dissipation sheet HRS may be reduced. Accordingly, the phenomenon of the first protective layer PRL1 being detached from the heat dissipation layer HRL may be prevented.

A maximum length of each of the second through holes TH2′ in the first direction DR1 (or the second direction DR2) may be about 1 mm or less. If the maximum length exceeds about 1 mm, particles in the heat dissipation layer HRL may be released to the outside, causing damage to the display panel DP, and external foreign substances and moisture may infiltrate into the heat dissipation layer HRL. Specifically, the maximum length may be about 0.1 mm to about 1 mm. In an embodiment, the maximum length may be about 0.1 mm to about 0.4 mm.

For example, as illustrated in FIG. 10, a planar shape of each of the water-repellent patterns RPP may be a ring shape, and each of the second through holes TH2′ may have a circular planar shape. A diameter DT′ of each of the second through holes TH2′ may be about 0.1 mm to about 1 mm. In an embodiment, the diameter DT may be about 0.1 mm to about 0.4 mm. However, the disclosure is not necessarily limited thereto, and a planar shape of each of the water-repellent patterns RPP and a planar shape of the second through holes TH2′ may vary depending on embodiments.

As a result, water-repellent patterns RPP may be disposed under the first protective layer PRL1 around each of the first through holes TH1. Accordingly, the water-repellent patterns RPP may cover the first surface S1 of the first protective layer PRL1 around each of the first through holes TH1. On the other hand, a second surface S2′ of the water-repellent member RPM' may be exposed to the outside around each of the first through holes TH1.

A contact angle of the second surface S2′ of the water repellent member RPM' with respect to water may be greater than a contact angle of the first surface S1 of the first protective layer PRL1 with respect to water. For example, the second surface S2′ of the water-repellent member RPM' may be more hydrophobic than the first surface S1 of the first protective layer PRL1.

According to embodiments, as the water-repellent member RPM' (for example, water-repellent patterns RPP) is disposed under the first protective layer PRL1 around each of the first through holes TH1, infiltration of moisture through the first through holes TH1 may be prevented. Accordingly, detachment of the first adhesive layer AL1 may be prevented, and detachment of the first protective layer PRL1 may be prevented. Accordingly, durability of the display device DD may be improved.

In particular, as the water-repellent member RPM' has a structure including water-repellent patterns RPP, the first surface S1 of the first protective layer PRL1 may be exposed from the water-repellent member RPM' between the first through holes TH1. For example, a portion of the first surface S1 of the first protective layer PRL1 may be exposed to the outside between the water-repellent patterns RPP.

Since a contact angle of the first surface S1 of the first protective layer PRL1 with respect to water is smaller than a contact angle of the second surface S2′ of the water-repellent member RPM' with respect to water, moisture may be more easily condensed on the first surface S1 of the first protective layer PRL1 rather than on the second surface S2′ of the water-repellent member RPM'. for example, a phenomenon of moisture condensing on the second surface S2′ of the water-repellent member RPM' may be further prevented due to an influence of the first surface S1 of the first protective layer PRL1. In other words, due to an influence of the first surface S1 of the first protective layer PRL1, a phenomenon of moisture condensing around each of the first through holes TH1 may be further prevented. Accordingly, infiltration of moisture through the first through holes TH1 may be further prevented. Accordingly, detachment of the first protective layer PRL1 may be further prevented.

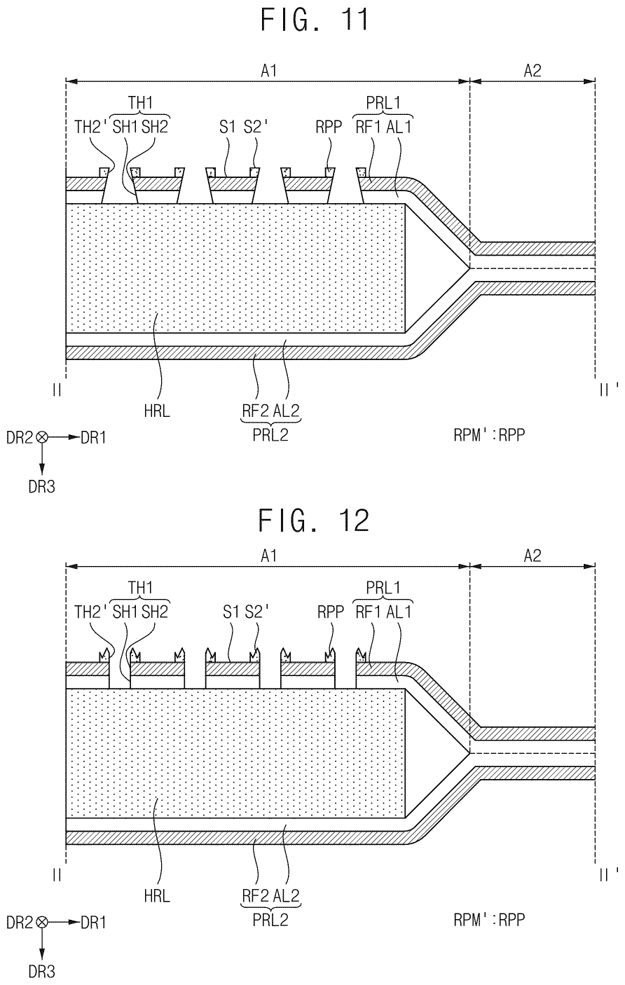

FIG. 11 is a schematic cross-sectional view illustrating another example taken along line II-II′ of FIG. 8.

An embodiment described with reference to FIG. 11 may be substantially the same as an embodiment described with reference to FIG. 9 except for a cross-sectional shape of each of the first through holes TH1 and the second through holes TH2′. Therefore, overlapping descriptions are omitted.

In FIG. 9, each of the first through holes TH1 and the second through holes TH2′ is illustrated to have a rectangular cross-sectional shape, but the disclosure is not necessarily limited thereto.

Referring to FIG. 11, a cross-sectional shape of each of the first through holes TH1 and the second through holes TH2′ may be a taper shape. Specifically, a width of each of the first through holes TH1 and the second through holes TH2′ may decrease as a distance from the heat dissipation layer HRL increases. In other words, each of the first through holes TH1 and the second through holes TH2′ may be a taper shape whose width decreases toward an opposite direction of the third direction DR3 (i.e., toward lower surface of the heat dissipation sheet HRS). Accordingly, infiltration of moisture through the first through holes TH1 and/or the second through holes TH2′ may be further prevented. Accordingly, detachment of the first protective layer PRL1 may be further prevented.

FIG. 12 is a schematic cross-sectional view illustrating still another example taken along line II-II′ of FIG. 8.

An embodiment described with reference to FIG. 12 may be substantially the same as an embodiment described with reference to FIG. 9 except for a concave-convex structure of the water-repellent member RPM. Therefore, overlapping descriptions are omitted.

In FIG. 9, the second surface S2′ of the water-repellent member RPM' is illustrated to have substantially no steps around the second through holes TH2′, but the disclosure is not necessarily limited thereto.

Referring to FIG. 12, the second surface S2′ of the water-repellent member RPM' may have a concavo-convex structure around the second through holes TH2. Each of the water-repellent patterns RPP may have the concavo-convex structure. The concavo-convex structure may be a structure in which at least one concave portion and at least one convex portion are repeated. Due to the concavo-convex structure, a roughness of the second surface S2′ of the water-repellent member RPM' around the second through holes TH2 may be improved. Accordingly, the contact angle of the second surface S2′ of the water-repellent member RPM' with respect to water around the second through holes TH2 may increase. Accordingly, infiltration of moisture through the first through holes TH1 and/or the second through holes TH2′ may be further prevented. Accordingly, detachment of the first protective layer PRL1 may be further prevented.

In an embodiment, a length of each of the concave portion and the convex portion in the first direction DR1 may be about 1 micrometer or less. In case that the length of each of the concave portion and the convex portion in the first direction DR1 satisfies the above-mentioned range, a roughness of the second surface S2′ of the water-repellent member RPM' around the second through holes TH2′ may be further improved. However, the length of each of the concave portion and the convex portion in the first direction DR1 is not necessarily limited thereto.

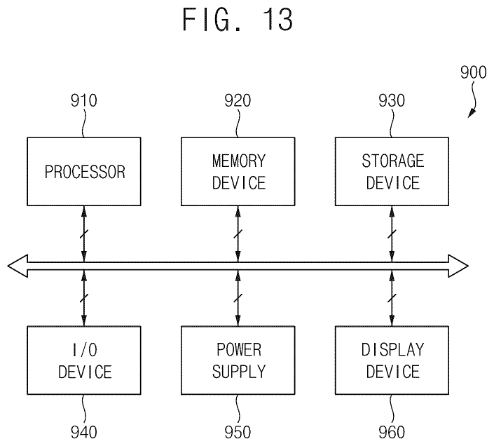

FIG. 13 is a schematic block diagram illustrating an electronic device according to an embodiment.

Referring to FIG. 13, in an embodiment, an electronic device 900 may include a processor 910, a memory device 920, a storage device 930, an input/output device 940, a power supply 950, and a display device 960. In this case, the display device 960 may correspond to the display device DD described with reference to FIGS. 1 to 12. The electronic device 900 may further include several ports capable of communicating with a video card, a sound card, a memory card, a USB device, and the like.

In an embodiment, the electronic device 900 may be implemented as a television. In another embodiment, the electronic device 900 may be implemented as a smart phone. However, the electronic device 900 is not limited thereto, and for example, the electronic device 900 may be implemented as a mobile phone, a video phone, a smart pad, a smart watch, a tablet PC, a vehicle navigation device, a computer monitor, a laptop computer, a head mounted display (HMD), and the like.

The processor 910 may perform certain calculations or tasks. The processor 910 may control the display device 960. In an embodiment, the processor 910 may be a microprocessor, a central processing unit (CPU), an application processor (AP), and/or the like. The processor 910 may be connected to other components through an address bus, a control bus, a data bus, and the like. The processor 910 may also be connected to an expansion bus, such as a peripheral component interconnect (PCI) bus.

The memory device 920 may store data necessary for the operation of the electronic device 900. For example, the memory device 920 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a non-volatile memory device such as a ferroelectric random access memory (FRAM) device and/or a volatile memory device such as a dynamic random access memory (DRAM) device, a static random access memory (SRAM) device, and a mobile DRAM device, and the like.

The storage device 930 may include a solid state drive (SSD), a hard disk drive (HDD), a CD-ROM, and the like.

The input/output device 940 may include input means such as a keyboard, keypad, touch pad, touch screen, mouse, and the like and output means such as a speaker, a printer, and the like.

The power supply 950 may supply power necessary for the operation of the electronic device 900. The display device 960 may be connected to other components through buses or other communication links. In an embodiment, the display device 960 may be included in the input/output device 940.

The disclosure may be applied to a display panel inspection device of various display devices. For example, the disclosure is applicable to a display panel inspection device of various display devices such as display devices for vehicles, ships and aircraft, portable communication devices, display devices for exhibition or information transmission, medical display devices, and the like.

In concluding the detailed description, those skilled in the art will appreciate that many variations and modifications may be made to the preferred embodiments without substantially departing from the principles and spirit and scope of the disclosure. Therefore, the disclosed preferred embodiments of the disclosure are used in a generic and descriptive sense only and not for purposes of limitation.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display panel including a light emitting element; and
a heat dissipation sheet disposed under the display panel and including:
a heat dissipation layer;
a first protective layer disposed under the heat dissipation layer and defining a plurality of first through holes; and
a water-repellent member disposed under the first protective layer, having a water-repellent surface, and defining a plurality of second through holes corresponding to the plurality of first through holes.

2. The display device of claim 1, wherein a contact angle of a surface of the water-repellent member with respect to water is greater than a contact angle of a surface of the first protective layer with respect to water.

3. The display device of claim 1, wherein a contact angle of a surface of the water-repellent member with respect to water is about 90 degrees or more.

4. The display device of claim 1, wherein the water-repellent member covers a surface of the first protective layer around each of the plurality of first through holes.

5. The display device of claim 1, wherein the water-repellent member includes at least one of a fluorine-based compound and a silicon-based compound.

6. The display device of claim 1, wherein one of the plurality of first through holes and a corresponding one of the plurality of second through holes are spatially connected to each other.

7. The display device of claim 1, wherein the first protective layer includes:
a first resin film disposed between the heat dissipation layer and the water-repellent member; and
a first adhesive layer disposed between the first resin film and the heat dissipation layer, and
wherein each of the plurality of first through holes includes a first sub-hole penetrating the first adhesive layer and a second sub-hole penetrating the first resin film.

8. The display device of claim 1, wherein
the heat dissipation sheet further includes a second protective layer disposed above the heat dissipation layer, and
the second protective layer includes:
a second resin film disposed between the heat dissipation layer and the display panel; and
a second adhesive layer disposed between the second resin film and the heat dissipation layer.

9. The display device of claim 8, wherein
the heat dissipation sheet includes a first area and a second area positioned outside the first area,
the first protective layer and the second protective layer are non-contact in the first area and contact each other in the second area, and
the water-repellent member overlaps the first area in a plan view.

10. The display device of claim 9, wherein the plurality of first through holes and the plurality of second through holes are defined in the first area.

11. The display device of claim 1, wherein the water-repellent member is a water-repellent film disposed in an integrated shape under the first protective layer and in which the plurality of second through holes are defined.

12. The display device of claim 1, wherein the water-repellent member includes a plurality of water-repellent patterns disposed under the first protective layer.

13. The display device of claim 12, wherein the plurality of water-repellent patterns are arranged to correspond to positions where the plurality of first through holes are defined.

14. The display device of claim 12, wherein
a planar shape of each of the plurality of water-repellent patterns is a ring-shape, and
each of the plurality of water-repellent patterns defines one of the plurality of second through holes.

15. The display device of claim 1, wherein a surface of the water-repellent member has a concave-convex structure around the plurality of second through holes.

16. The display device of claim 1, wherein a width of each of the plurality of second through holes decreases as a distance from the heat dissipation layer increases.

17. The display device of claim 1, wherein the heat dissipation layer includes graphite.

18. A display device comprising:
a display panel; and
a heat dissipation sheet disposed under the display panel, wherein
the display panel includes:
a base substrate;
a transistor disposed on the base substrate; and
a light emitting element electrically connected to the transistor, and the heat dissipation sheet includes:
a heat dissipation layer disposed under the display panel, including graphite, and having a porous structure;
a first protective layer disposed under the heat dissipation layer and defining a plurality of first through holes;
a water-repellent member disposed under the first protective layer, having a water-repellent surface, and defining a plurality of second through holes corresponding to the plurality of first through holes; and
a second protective layer disposed above the heat dissipation layer.

19. The display device of claim 18, wherein
a contact angle of a surface of the water-repellent member with respect to water is greater than a contact angle of a surface of the first protective layer with respect to water, and
the contact angle of the surface of the water-repellent member with respect to water is about 90 degrees or more.

20. The display device of claim 18, wherein
the heat dissipation sheet includes a first area and a second area positioned outside the first area,
the first protective layer and the second protective layer are non-contact in the first area and contact each other in the second area,
the water-repellent member overlaps the first area in a plan view, and
the plurality of first through holes and the plurality of second through holes are defined in the first area.

21. An electronic device comprising:
a display device; and
a processor which controls the display device,
wherein the display device includes:
a display panel including a light emitting element; and
a heat dissipation sheet disposed under the display panel and including:
a heat dissipation layer;
a first protective layer disposed under the heat dissipation layer and defining a plurality of first through holes; and
a water-repellent member disposed under the first protective layer, having a water-repellent surface, and defining a plurality of second through holes corresponding to the plurality of first through holes.
